(19) United States
(12) Patent Application Publication
(10) Pub. No.: US 2016/0268388 A1
(43) Pub. Date: Sep. 15, 2016

(54) NON-VOLATILE MEMORY DEVICE AND METHOD FOR MANUFACTURING SAME

(71) Applicant: Kabushiki Kaisha Toshiba, Minato-ku (JP)

(72) Inventors: Hiroshi ITOKAWA, Oita (JP); Kenichiro TORATANI, Kuwana (JP)

(73) Assignee: Kabushiki Kaisha Toshiba, Minato-ku (JP)

(21) Appl. No.: 14/838,459

(22) Filed: Aug. 28, 2015

Related U.S. Application Data
(60) Provisional application No. 62/132,756, filed on Mar. 13, 2015.

(51) Int. Cl. H01L 29/423; H01L 29/49; H01L 29/66; H01L 21/28; H01L 21/02; H01L 29/788; H01L 29/51

(52) U.S. Cl. CPC H01L 29/42332; H01L 29/788; H01L 29/4925; H01L 29/518; H01L 29/517; H01L 21/28273; H01L 21/0217; H01L 21/02181; H01L 21/02271; H01L 29/66825

(57) ABSTRACT

A non-volatile memory device includes a semiconductor body extending in a first direction, an electrode extending in a second direction crossing the first direction, a first floating gate provided between the semiconductor body and the electrode, and a second floating gate provided between the first floating gate and the electrode. The first floating gate is provided via an insulating film on the semiconductor body and has a side surface in the second direction. The second floating gate has a side surface in the second direction. The device further includes a silicon nitride film in contact with the side surface of the second floating gate and a first insulating film that covers the silicon nitride film and is in contact with the side surface of the first floating gate.

### CROSS-REFERENCE TO RELATED APPLICATIONS

This application is based upon and claims the benefit of priority from U.S. Provisional Patent Application 62/132,756 filed on Mar. 13, 2015; the entire contents of which are incorporated herein by reference.

### FIELD

Embodiments described herein relate generally to a non-volatile memory device and a method for manufacturing the same.

### BACKGROUND

In order to increase the capacity of a non-volatile memory device, the memory cell thereof is required to achieve multivalued operation and improvement in data retention characteristics. For instance, the memory cell of a NAND semiconductor memory device has a structure for retaining a large amount of charge in a floating gate and suppressing the temporal change of the amount of charge. There is demand for a new structure for improving these characteristics.

### BRIEF DESCRIPTION OF THE DRAWINGS

FIG. 1 is a plan view schematically showing a non-volatile memory device according to an embodiment;

FIG. 2 is a schematic sectional view showing the memory cell of the non-volatile memory device according to the embodiment;

FIG. 3 is an energy band diagram of the memory cell according to the embodiment;

FIGS. 4A to 4G are schematic sectional views showing a process for manufacturing the memory cell according to the embodiment;

FIG. 5 is a perspective view schematically showing the memory cell according to the embodiment; and

FIG. 6 is a graph showing the characteristics of an insulating film according to the embodiment.

### DETAILED DESCRIPTION

According to one embodiment, a non-volatile memory device includes a semiconductor body extending in a first direction, an electrode extending in a second direction crossing the first direction, a first floating gate provided between the semiconductor body and the electrode, and a second floating gate provided between the first floating gate and the electrode. The first floating gate is provided via an insulating film on the semiconductor body and has a side surface in the second direction. The second floating gate has a side surface in the second direction. The device further includes a silicon nitride film in contact with the side surface of the second floating gate and a first insulating film that covers the silicon nitride film and is in contact with the side surface of the first floating gate.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

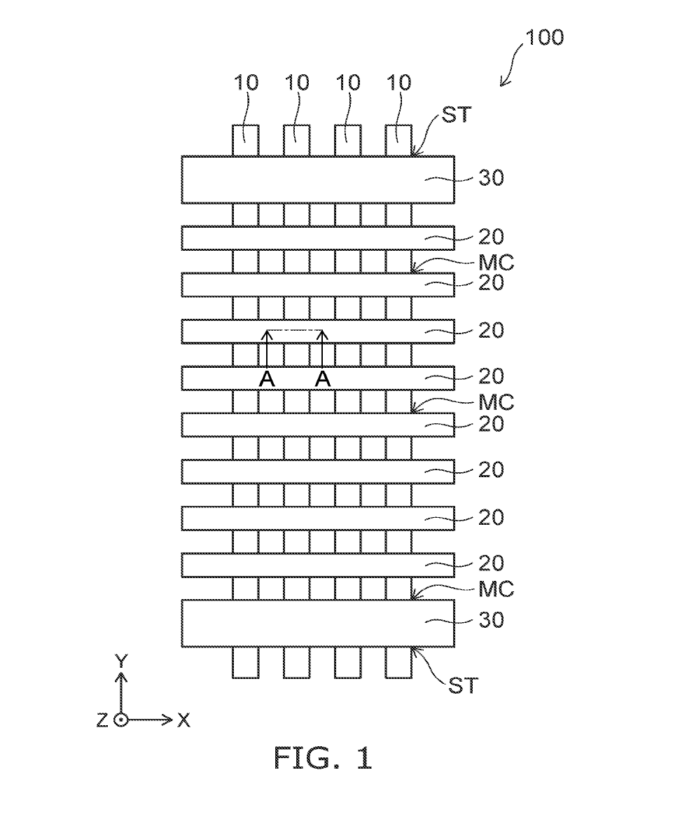

FIG. 1 is a plan view schematically showing a non-volatile memory device 100 according to an embodiment. The non-volatile memory device 100 is e.g. a NAND semiconductor memory device. The non-volatile memory device 100 includes a semiconductor body (hereinafter, channel body 10), an electrode (hereinafter, control electrode 20), and a select gate 30.

As shown in FIG. 1, the non-volatile memory device 100 includes a plurality of channel bodies 10. Each channel body 10 is provided like a stripe extending in a first direction (hereinafter, Y-direction) on e.g. a silicon wafer. The channel bodies 10 are arranged in the X-direction.

The control electrode 20 and the select gate 30 extend in a second direction crossing the channel body 10. In this example, the control electrode 20 and the select gate 30 extend in the X-direction orthogonal to the Y-direction. However, the direction is not limited thereto. That is, the control electrode 20 and the select gate 30 do not need to be orthogonal to the channel body 10.

The control electrodes 20 are arranged in the Y-direction. The select gates 30 are disposed on both sides of the control electrodes 20 arranged in the Y-direction. A memory cell MC is provided in the crossing portion of the control electrode 20 and the channel body 10. A select transistor ST is provided in each crossing portion of the select gate 30 and the channel body 10.

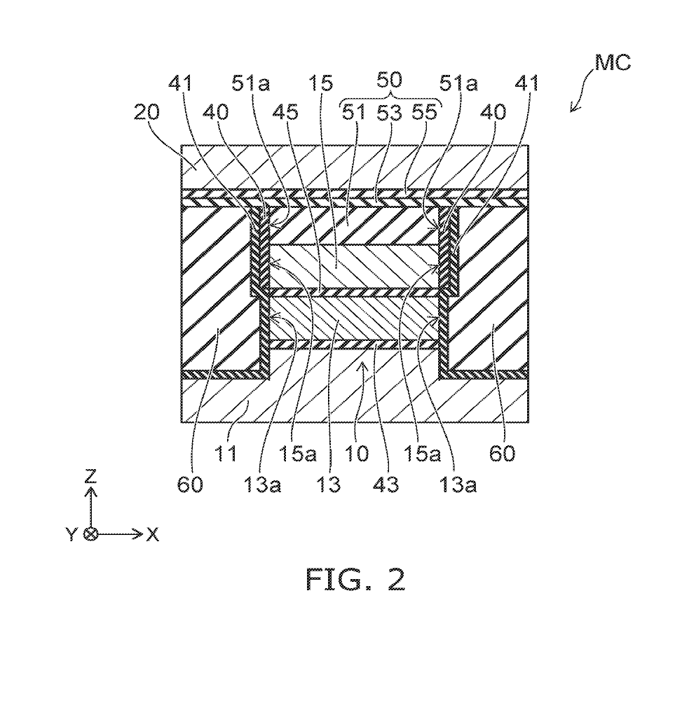

FIG. 2 is a schematic sectional view showing the memory cell MC of the non-volatile memory device 100 according to the embodiment. FIG. 2 is a schematic view showing e.g. the cross section taken along line A-A shown in FIG. 1.

The memory cell MC includes a first floating gate 13 and a second floating gate 15 between the channel body 10 and the control electrode 20. The first floating gate 13 is provided on the channel body 10. The second floating gate 15 is provided between the first floating gate 13 and the control electrode 20. The channel body 10 is formed by e.g. processing the surface of a p-type well 11 provided in the silicon wafer into a stripe.

The first floating gate 13 has a side surface 13a in the second direction. The side surface 13a is parallel to a third direction (hereinafter, Z-direction) and the Y-direction, for example. The Z-direction is directed from the channel body 10 to the control electrode 20. The second floating gate 15 has a side surface 15a in the second direction. The side surface 15a is parallel to the Z-direction and the Y-direction, for example. The memory cell MC includes a silicon nitride film 40 in contact with the side surface 15a of the second floating gate and a first insulating film (hereinafter, insulating film 41) in contact with the side surface 13a of the first floating gate. The insulating film 41 is e.g. a silicon oxide film.

The memory cell MC includes a second insulating film (hereinafter, tunnel insulating film 43) provided between the channel body 10 and the first floating gate 13, and a third insulating film (hereinafter, intermediate insulating film 45) provided between the first floating gate 13 and the second floating gate 15.

The memory cell MC further includes a fourth insulating film (hereinafter, block insulating film 50) provided between the second floating gate 15 and the control electrode 20. The block insulating film 50 includes e.g. a material having a higher permittivity than the tunnel insulating film 43 and the intermediate insulating film 45.

The tunnel insulating film 43 and the intermediate insulating film 45 are e.g. silicon oxide films. The block insulating film 50 includes a high-permittivity material such as hafnium oxide. The block insulating film 50 includes e.g. a first film 51, a second film 53, and a third film 55.

The first film 51 and the third film 55 are e.g. high-permittivity films such as hafnium oxide. The first film 51 may include a material different from that of the third film 53. The second film 53 is e.g. a silicon oxide film. The first film 51 has a side surface 51a parallel to the Z-direction and the Y-direction. The silicon nitride film 40 is also in contact with the first film 51 as well as the side surface 15a of the second floating gate 15.

Furthermore, an insulating film 60 is provided between the adjacent channel bodies 10. The insulating film 60 is what is called an STI (shallow trench isolation) film insulating the memory cells MC adjacent in the X-direction from each other. The insulating film 60 is e.g. a silicon oxide film or a silicon-containing oxide film.

In this example, the insulating film 41 and the insulating film 60 are described as being different films. However, instead of providing the insulating film 41, the insulating film 60 may cover the silicon nitride film 40 and be in contact with the first floating gate 13. The insulating film 41 and the insulating film 60 preferably have a wider energy bandgap than a silicon nitride film. The insulating film 41 and the insulating film 60 preferably have a smaller permittivity than a silicon nitride film.

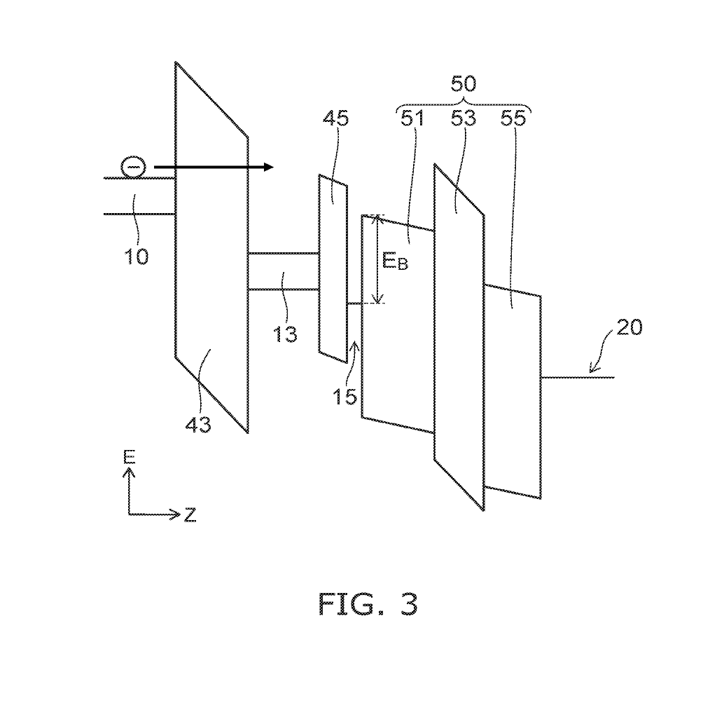

FIG. 3 is an energy band diagram of the memory cell according to the embodiment. In FIG. 3, the vertical direction represents energy level E. The horizontal direction represents position in the Z-direction.

The memory cell MC includes a first floating gate 13 and a second floating gate 15. This can increase the accumulated amount of charge injected from the channel body 10 through the tunnel insulating film 43.

The first floating gate 13 is provided between the tunnel insulating film 43 and the intermediate insulating film 45. The first floating gate 13 is e.g. a silicon-containing conductive film. The first floating gate 13 can be e.g. an n-type silicon film or an n-type silicon germanium film. The first floating gate 13 may be e.g. a polycrystalline semiconductor film.

The second floating gate 15 is provided between the intermediate insulating film 45 and the block insulating film 50. The second floating gate 15 is preferably made of e.g. a material having a large energy barrier ΔE_{B} at the interface with the block insulating film 50. In other words, the second floating gate 15 is preferably made of a material having a large work function. The second floating gate 15 is preferably made of e.g. a metallic material having a work function comparable to or larger than that of p-type silicon. For instance, the work function of the material used for the second floating gate 15 is larger than the work function of the material used for the first floating gate 13.

The second floating gate 15 can be made of e.g. titanium nitride (TiN), tantalum nitride (TaN), or tungsten silicon (WSi). Use of such materials can suppress migration of charge from the second floating gate to the control electrode 20 and improve the charge retention characteristics of the memory cell MC.

Furthermore, the first film 51 of the block insulating film 50 is in contact with the second floating gate 15 and made of a high-permittivity film such as hafnium oxide. This can further increase the energy barrier ΔE_{B}. The second floating gate is preferably made of a material having low reactivity with the first film 51.

For instance, ruthenium (Ru) has a large work function among metal materials. However, ruthenium has high reactivity with a high-permittivity film. Ruthenium is easily diffused into the block insulating film 50 by e.g. heat treatment in the process for manufacturing the memory cell MC. This may degrade the insulation property of the block insulating film 50 and compromise the charge retention characteristics of the memory cell MC. In contrast, titanium nitride (TiN), tantalum nitride (TaN), and tungsten silicon (WSi) have low reactivity with a high-permittivity film, and can achieve high charge retention characteristics.

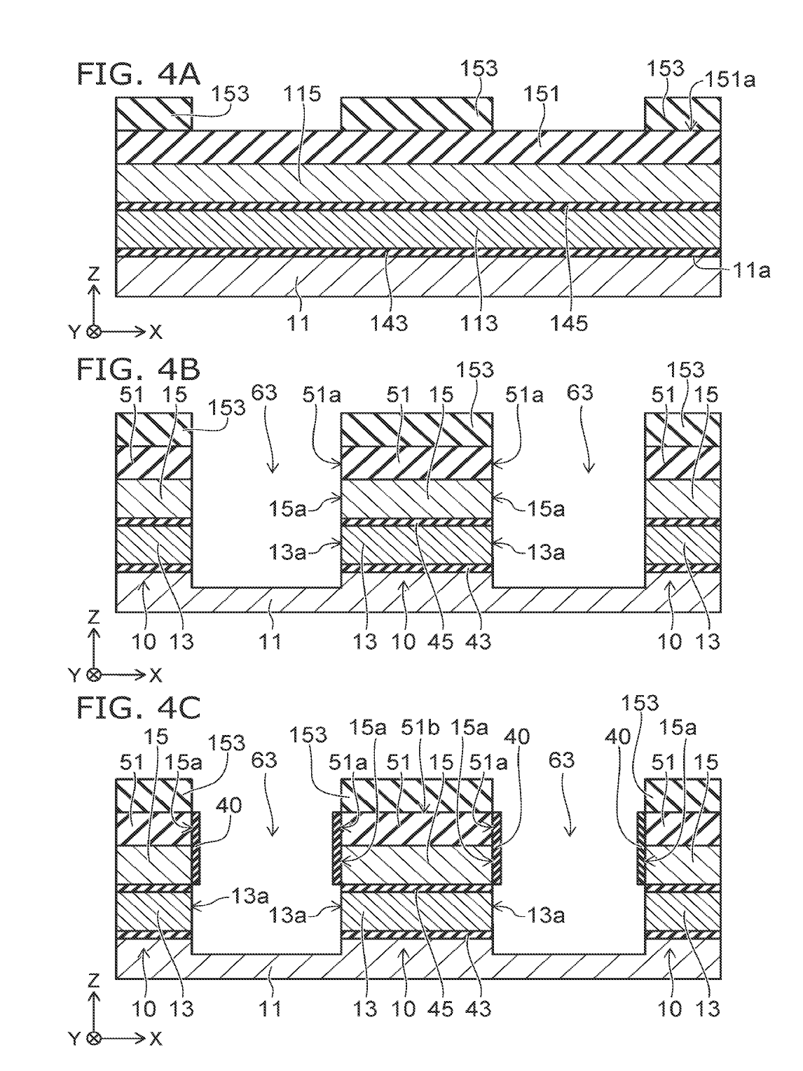

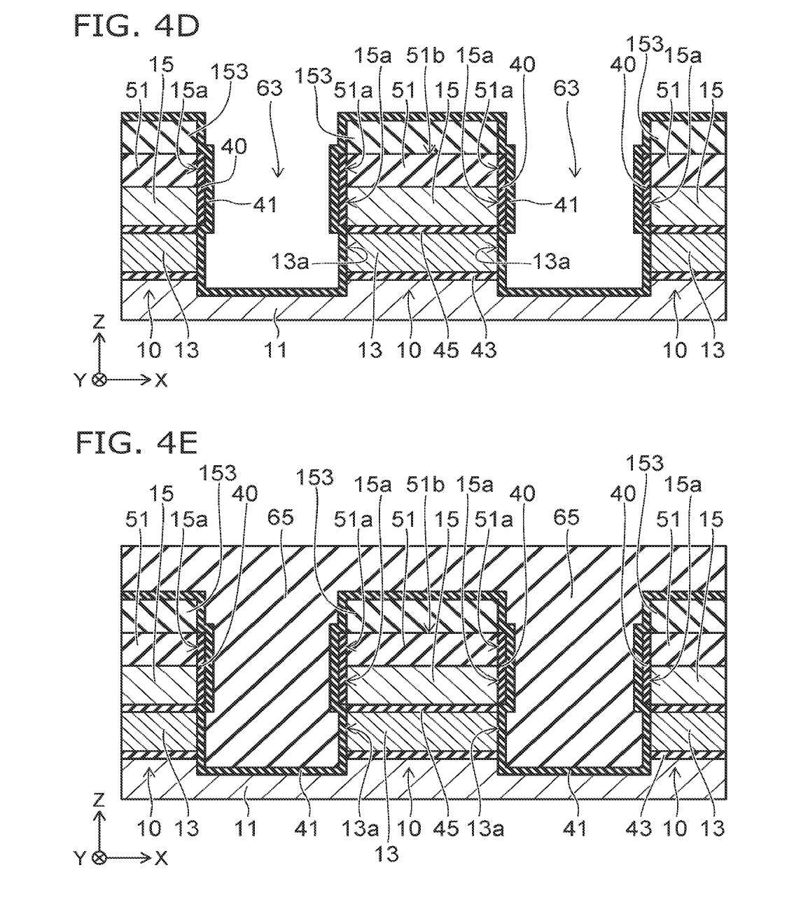

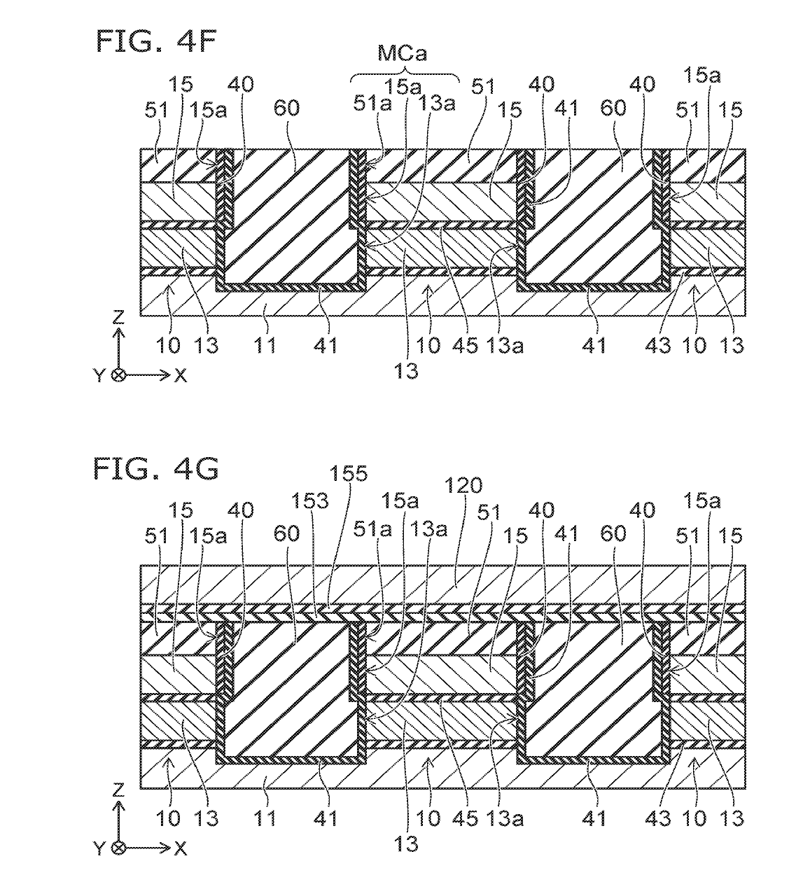

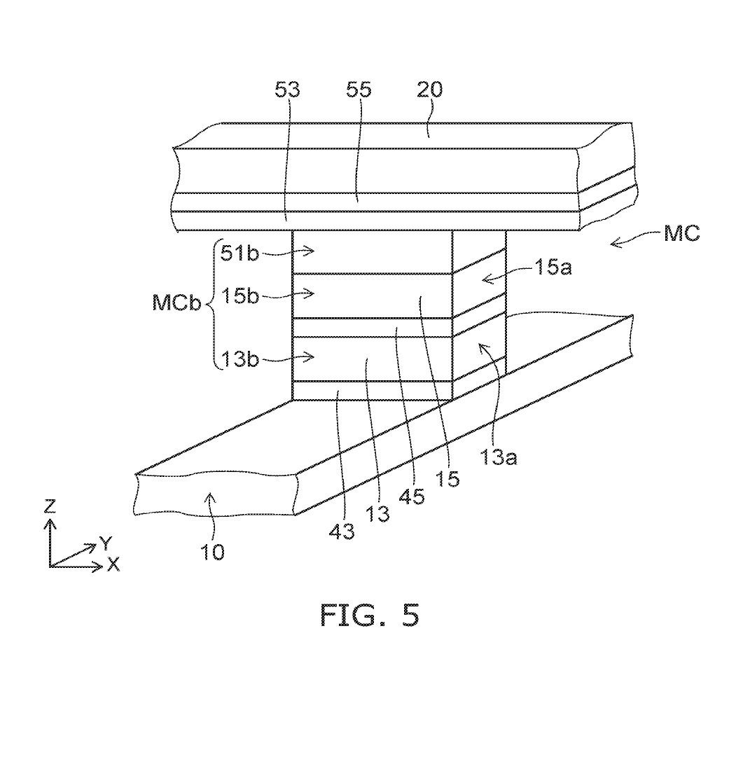

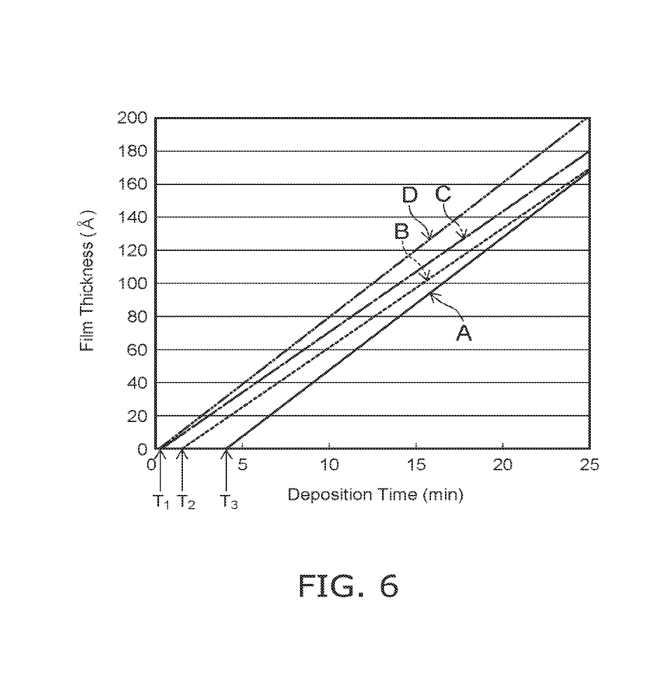

Next, a method for manufacturing the non-volatile memory device 100 is described with reference to FIGS. 4A-4B, FIG. 5, and FIG. 6. FIGS. 4A to 4G are schematic sectional views showing the process for manufacturing the memory cell MC according to the embodiment. FIG. 5 is a perspective view schematically showing the memory cell MC according to the embodiment. FIG. 6 is a graph showing the characteristics of the insulating film according to the embodiment.

As shown in FIG. 4A, for instance, a silicon oxide film 143, a polysilicon film 113, a silicon oxide film 145, a TiN film 115, and a hafnium oxide film 151 are sequentially stacked on a p-type well 11. Furthermore, a hard mask 153 is selectively formed on the hafnium oxide film 151. The hard mask 153 is formed like a stripe extending in the Y-direction. The hard mask 153 is e.g. a silicon oxide film.

Next, as shown in FIG. 4B, a trench 63 is formed using the hard mask 153 as an etching mask. The trench 63 is formed from the upper surface 151a of the hafnium oxide film 151 to a depth reaching the p-type well 11. The trench 63 divides e.g. the multilayer body including the silicon oxide film 143, the polysilicon film 113, the silicon oxide film 145, the TiN film 115, and the hafnium oxide film 151 into stripes extending in the Y-direction. Thus, the silicon oxide film 143 is divided into tunnel insulating films 43. The polysilicon film 113 is divided into first floating gates 13. The silicon oxide film 145 is divided into intermediate insulating films 45. The TiN film 115 is divided into second floating gates 15. The hafnium oxide film 151 is divided into first films 51.

The trench 63 forms a plurality of channel bodies 10 on the upper surface 11a of the p-type well 11. The channel body 10 is shaped like a stripe extending in the Y-direction. The channel bodies 10 are juxtaposed in the X-direction.

As shown in FIG. 4C, for instance, a silicon nitride film 40 is selectively formed on the side surface 51a of the first film 51 and the side surface 15a of the second floating gate 15. The silicon nitride film 40 can be selectively formed on TiN and hafnium oxide by e.g. chemical vapor deposition (CVD). The silicon nitride film 40 is formed in contact with the side surface 15a of the second floating gate 15 and the side surface 51a of the first film 51.

FIG. 6 shows the deposition characteristics of a silicon nitride film deposited on a silicon oxide film, a TiN film, a hafnium oxide film, and a hafnium oxynitride film by ALD (atomic layer deposition), which is one of CVD techniques. The horizontal axis represents deposition time (minutes). The vertical axis represents deposition film thickness (angstroms, Å). In FIG. 6, symbol A indicates deposition characteristics on the silicon oxide film and silicon. Symbol B indicates deposition characteristics on the TiN film. Symbol C indicates deposition characteristics on the hafnium oxide film. Symbol D indicates deposition characteristics on the hafnium oxynitride film.

As shown in FIG. 6, it is found that there is a time delay called incubation time between the start of growth, i.e., the start of supplying a source gas, and the time when the deposition of the silicon nitride film actually starts. The timing when the deposition of the silicon nitride film starts is varied depending on the underlying material. For instance, in the case of the hafnium oxide film and the hafnium oxynitride film, the deposition of the silicon nitride film starts at time t₁ immediately after the start of growth. In the case of the TiN film, the deposition starts at time t₂ slightly later than t₁. In contrast, in the case of the silicon oxide film and silicon, the deposition of the silicon nitride film starts at time t₃ later than t₁ and t₂. Thus, the silicon nitride film can be selectively deposited using these differences in incubation time.

For instance, the deposition time of the silicon nitride film 40 can be made shorter than t₃. Thus, the silicon nitride film 40 covering the first film 51 made of a hafnium oxide film and the side surface 15a of the second floating gate 15 made of a TiN film can be formed without depositing the silicon nitride film 40 on the side surface 13a of the floating gate 13 made of a polysilicon film. In this example, the silicon nitride film 40 is also not deposited on the end surfaces of the tunnel insulating film 43 and the intermediate insulating film 45 made of a silicon oxide film and on the p-type well 11 exposed at the bottom of the trench 63.

In ALD technique, a silicon source material and a nitrogen source material are supplied alternately. Thus, the deposition time can be replaced by the number of cycles of supplying the silicon source material and the nitrogen source material. That is, in ALD technique, the silicon nitride film 40 can be selectively formed by controlling the number of cycles of supplying the source material.

Next, as shown in FIG. 4D, an insulating film 41 is formed to cover the inner surface of the trench 63 and the hard mask 153. The insulating film 41 is e.g. a silicon oxide film formed by CVD technique. For instance, the insulating film 41 is formed so as to cover the silicon nitride film 40 and to be in contact with the side surface 13a of the first floating gate 13.

As shown in FIG. 4E, an insulating film 65 is formed on the insulating film 41 and buried inside the trench 63. The insulating film 65 is e.g. a silicon oxide film formed by TEOS (tetraethoxysilane)-CVD technique or spin coating technique.

Next, as shown in FIG. 4F, the insulating film 65, the insulating film 41, and the hard mask 153 are removed while leaving the portion (hereinafter, insulating film 60) buried in the trench 63. The insulating film 65, 41 and the hard mask 153 are removed by e.g. CMP (chemical mechanical polishing) technique. The insulating film 60 buried in the trench 63 functions as e.g. STI (shallow trench isolation).

The insulating film 60 is preferably subjected to e.g. heat treatment at a temperature of 400-500° C. in an oxygen-containing atmosphere. This can promote interatomic bonding in the insulating film 60 and reduce dangling bonds of silicon atoms. As a result, the insulation property of the insulating film 60 is improved. For instance, the leakage current is reduced.

Furthermore, in the process of heat treating the insulating film 60, the silicon nitride film 40 covering the side surface 15a of the second floating gate 15 can prevent intrusion of oxygen atoms. For instance, when TiN is heat treated in an oxygen atmosphere, nitrogen is replaced by oxygen to form titanium oxide (TiO) having insulation property. Thus, the conductivity of a TiN film is decreased when the TiN film is heat treated in an oxygen atmosphere. In contrast, in the embodiment, the side surface 15a of the second floating gate 15 is covered with a silicon nitride film. This can suppress oxidation of the second floating gate 15 at the time of heat treatment and maintain its conductivity.

Oxidation of TiN at the time of heat treatment can be suppressed also when e.g. the silicon nitride film 40 is formed so as to entirely cover the side surface MCa of the memory cell MC. However, a silicon nitride film has a higher permittivity than a silicon oxide film, and carrier traps are formed more easily in the silicon nitride film. Thus, if the side surface 13a of the first floating gate 13 and the end surface of the tunnel insulating film 43 are covered with the silicon nitride film 40, leakage of charge may occur from the first floating gate 13 through the silicon nitride film 40 to the channel body 10. This may degrade the charge retention characteristics of the memory cell MC. Furthermore, the silicon nitride film 40 entirely covering the side surface MCa of the memory cell MC increases parasitic capacitance between the adjacent memory cells MC. Thus, the capacitive coupling ratio is decreased between the control gate and the floating gate and between the floating gate and the channel body. This may increase the data write voltage or data erase voltage of the memory cell MC.

Thus, in the embodiment, the silicon nitride film 40 is selectively formed so as to cover the side surface 15a of the second floating gate 15 but not to cover the side surface 13a of the first floating gate 13 and the end surface of the tunnel insulating film 43. This can prevent the leakage of charge from the first floating gate 13 to the channel body 10 and avoid the degradation of charge retention characteristics of the memory cell MC. Furthermore, the increase of parasitic capacitance between the adjacent memory cells can be suppressed.

Next, as shown in FIG. 4G, an insulating film 153, an insulating film 155, and a conductive film 120 are sequentially formed on the first film 51 and the insulating film 60. The insulating film 153 is e.g. a silicon oxide film. The insulating film 155 is e.g. a hafnium oxide film. The conductive film 120 is e.g. a tungsten film. The conductive film 120 may have a multilayer structure including e.g. a TiN film in contact with the insulating film 155 and a tungsten film formed on the TiN film.

Next, as shown in FIG. 5, the insulating films 153, 155 and the conductive film 120 are shaped like a stripe extending in the X-direction. Thus, a plurality of control electrodes 20 arranged in the Y-direction are formed.

Furthermore, the first film 51, the second floating gate 15, the intermediate insulating film 45, and the first floating gate 13 are selectively etched to form a side surface MCb parallel to the X-direction and the Z-direction of the memory cell MC. The side surface MCb includes a side surface 13b of the first floating gate 13, a side surface 15b of the second floating gate 15, and a side surface 51b of the first film 51. In the example shown in FIG. 5, the tunnel insulating film 43 is also selectively etched. However, the embodiment is not limited thereto. For instance, the tunnel insulating film 43 may extend in the Y-direction on the channel body 10.

In FIG. 5, the insulating films are not shown. However, for instance, a second silicon nitride film in contact with the side surface 15b of the second floating gate 15 may be selectively formed, and a fifth insulating film covering the second silicon nitride film and the side surface 13b of the first floating gate may be formed. The fifth insulating film is e.g. a silicon oxide film.

As described above, the memory cell MC of the non-volatile memory device according to the embodiment includes a first floating gate 13 including silicon and a second floating gate 15 including a metallic material. The side surface of the second floating gate 15 is selectively covered with a silicon nitride film. This can suppress degradation of the second floating gate 15 at the time of heat treatment. Thus, a memory cell MC having a large amount of charge retention and high charge retention characteristics can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile memory device comprising:
a semiconductor body extending in a first direction;
an electrode extending in a second direction crossing the first direction;
a first floating gate provided between the semiconductor body and the electrode, the first floating gate being provided via an insulating film on the semiconductor body and having a side surface in the second direction;
a second floating gate provided between the first floating gate and the electrode, the second floating gate having a side surface in the second direction;
a silicon nitride film in contact with the side surface of the second floating gate; and
a first insulating film covering the silicon nitride film, the first insulating film being in contact with the side surface of the first floating gate.

2. The device according to claim 1, wherein the first floating gate is a conductive film including silicon.

3. The device according to claim 1, wherein the second floating gate includes a metallic material.

4. The device according to claim 1, wherein the second floating gate includes a material having a larger work function than a work function of the first floating gate.

5. The device according to claim 1, wherein the second floating gate includes titanium nitride.

6. The device according to claim 1, wherein the second floating gate includes at least one of tantalum nitride and tungsten silicon.

7. The device according to claim 1, wherein the first insulating film has a permittivity lower than a permittivity of the silicon nitride film.

8. The device according to claim 1, wherein the first insulating film has a bandgap larger than a bandgap of the silicon nitride film.

9. The device according to claim 1, wherein the first insulating film is a silicon oxide film.

10. The device according to claim 1, further comprising:
a second insulating film provided between the semiconductor body and the first floating gate;
a third insulating film provided between the first floating gate and the second floating gate; and
a fourth insulating film provided between the second floating gate and the electrode, the fourth insulating film including a material having a higher permittivity than a permittivity of the second insulating film and a permittivity of the third insulating film.

11. The device according to claim 10, wherein the third insulating film includes hafnium oxide.

12. The device according to claim 10, wherein the silicon nitride film is in contact with at least a part of the third insulating film.

13. A method for manufacturing a non-volatile memory device, comprising:
forming a conductive layer including silicon on a semiconductor layer;
forming a metal layer having a larger work function than the conductive layer on the conductive layer;
forming the conductive layer and the metal layer into a stripe shape;
selectively forming a silicon nitride film in contact with the metal layer at a side surface of the stripe; and
forming an oxide film covering the silicon nitride film and being in contact with the conductive layer at the side surface of the stripe.

14. The method according to claim 13, wherein the silicon nitride film is formed by alternately supplying a silicon source material and a nitrogen source material in a chemical vapor deposition.

15. The method according to claim 13, wherein the silicon nitride film is formed during a period after starting a deposition of the silicon nitride on the metal layer and before timing of when a silicon nitride deposition begins on the conductive layer.

16. The method according to claim 13, wherein the oxide film is heated in an oxygen-containing atmosphere.
